(19) United States
(12) Patent Application Publication
(10) Pub. No.: US 2012/0161809 A1
(43) Pub. Date: Jun. 28, 2012

(54) POWER SUPPLY TESTING DEVICE AND COMPUTER SYSTEM HAVING SAME

(75) Inventor: HUI LI, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/094,759

(22) Filed: Apr. 26, 2011

(30) Foreign Application Priority Data
Dec. 28, 2010 (CN) 201010609017.9

(51) Int. Cl. G01R 31/40

(52) U.S. Cl. 324/764.01

(57) ABSTRACT

A power supply testing device includes an input end electrically connected to a power supply, an output end electrically connected to a motherboard of a computer, and a testing interface unit electrically connected between the input end and the output end. The testing interface unit includes a number of testing connector groups each corresponding to a voltage of output current of the power supply. Each of the test connector groups is configured for parameters testing of the corresponding voltage from the output current.

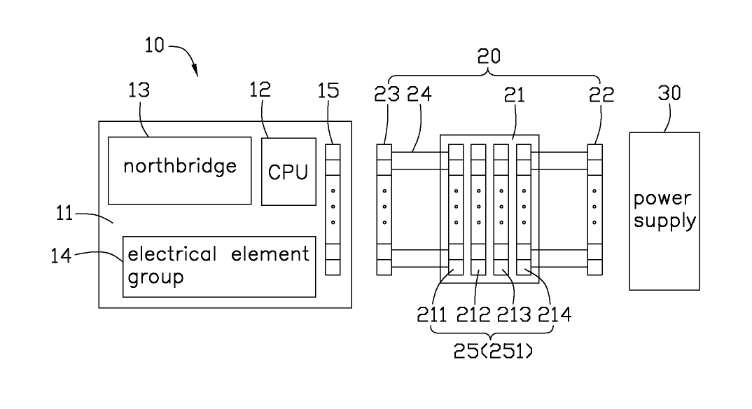

### BACKGROUND

1. Technical Field

The present disclosure relates to a power supply testing device and a computer system having the power supply testing device, and particularly, relates to a power supply testing device for testing parameters of a power supply of the computer system.

2. Description of Related Art

A power supply for a computer is configured for converting alternating current (AC) into direct current (DC), which is used by the computer. The power supply can output current having different voltages for different electrical elements, such as a CPU, hard disk, and CD-ROM drive.

Voltages of the output currents of the power supply need to be kept at a predetermined level for normal function of the electrical elements. For example, the power supply can output current having a voltage of +12V for the hard disk and the CD-ROM drive. If the voltage of the current is lower than or greater than +12V, the efficiency of the hard disk and the and the CD-ROM may be reduced, even worse, the hard disk and the CD-ROM drive may be damaged. Therefore, it is important to test parameters related to the voltage of the output current, such as ripple and noise of the output current. An external testing device is typically used to test the parameters of the output current. However, a test lead of the external testing device needs to frequently contact with the power supply and the electrical elements, this can be troublesome. Furthermore, the power supply and the electrical elements may be damaged by the test lead of the external testing device.

What is needed therefore is a power supply testing device and a computer system having the power supply testing device addressing the limitations described.

### BRIEF DESCRIPTION OF THE DRAWINGS

The figure is a schematic view of a computer system having a power supply testing device, according to an exemplary embodiment of the present disclosure.

### DETAILED DESCRIPTION

Referring to the figure, a computer system 100, according to an exemplary embodiment, is shown. The computer system 100 includes a motherboard 10, a power supply testing device 20 and a power supply 30.

The motherboard 10 includes a circuit board 11, a CPU 12, a Northbridge 13, a power connector unit 15 and an electrical element group 14. The CPU 12, the Northbridge 13 and the electrical element group 14 are positioned on the circuit board 11. The electrical element group 14 may be include resistors, capacitors, and functional integrated circuits (not shown).

The power connector unit 15 is configured for electrically connecting to the power supply 30 and supplying electrical power for the CPU, the Northbridge 13 and the other electrical elements 14. The power connector unit 15 includes different types of connectors, such as 24-pin connector and 4-pin connector, according to different types of electrical elements to be powered. For example, a 24-pin connector includes a number of input ends for inputting different currents with different voltages, in this embodiment, the currents with voltages of +12V, +3.3V, +5V, −12V and +5V standby can be input through the 24 pin connector.

The power supply testing device 20 includes a circuit board 21, an input end 22, an output end 23, a testing interface unit 25. The input end 22 is configured for electrically connecting to the power supply 30, the output end 23 is configured for connecting to the power connector unit 15. The testing interface unit 25 is positioned on the circuit 21 and is electrically connected to the input end 22 and the output end 23 via a number of wires 24. The testing interface unit 25 includes a number of test connector groups 251. Each test connector group 251 is corresponding to a voltage from the output current of the power supply 30, and each test connector group 251 includes a first test connector 211, a second test connector 212, a third test connector 213 and a fourth test connector 214. In this embodiment, the number of the test connector groups 251 is five. In other embodiments, the number of the test connector groups 251 can be increased or reduced corresponding to the changing of the number of voltages of output current of the power supply 30.

The first test connectors 211 are configured for voltage testing. The third test connectors 213 are configured for ripple testing and noise testing. The second test connectors 212 are configured for connecting to filter capacitors (typically two multiple capacitors respectively with capacitance of 0.1 μF and 10 μF) during the ripple testing and noise testing. The fourth test connectors 214 are configured for current testing by connecting to a precision resistor.

In testing, a multimeter (not shown) or an oscilloscope (not shown) can be in direct contact with the testing interface unit 25 to test parameters of the current output by the power supply. Therefore, it is convenient to test parameters of the current output with the power supply, in addition, the damage to the power supply or the motherboard because of testing is avoided.

It is believed that the present embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

What is claimed is:

1. A power supply testing device for testing parameters of current between a power supply and a motherboard of a computer, comprising:
an input end for being electrically connected to the power supply;
an output end for being electrically connected to the motherboard; and
a testing interface unit electrically connected between the input end and the output end, the testing interface unit comprising a plurality of test connector groups each corresponding to a voltage of output current of the power supply, each of the test connector groups configured for parameters testing of the corresponding voltage from the output current.

2. The power supply testing device of claim 1, wherein each test connector group comprises a first test connector, a second test connector, a third test connector and a fourth test connector.

3. The power supply testing device of claim 2, wherein the first test connector is configured for voltage testing.

4. The power supply testing device of claim 2, wherein the third test connector is configured for ripple testing and noise testing.

5. The power supply testing device of claim 4, wherein the second test connector is configured for connecting to filter capacitors during the ripple testing and noise testing.

6. The power supply testing device of claim 5, wherein the filter capacitors are two multiple capacitors respectively with capacitance of 0.1 μF and 10 μF.

7. The power supply testing device of claim 2, wherein the fourth test connector is configured for current testing by connecting to a precision resistor.

8. The power supply testing device of claim 1, further comprising a circuit board, the test connector groups being positioned on the circuit board.

9. A computer system, comprising:
a motherboard;
a power supply; and
a power supply testing device electrically connected between the power supply and the motherboard, comprising
an input end electrically connected to the power supply;
an output end electrically connected to the motherboard; and
a testing interface unit electrically connected between the input end and the output end, the testing interface unit comprising a plurality of test connector groups each corresponding to a voltage of output current of the power supply, each of the test connector groups configured for parameters testing of the corresponding voltage of the output current.

10. The computer system of claim 9, wherein each test connector group comprises separately located a first test connector, a second test connector, a third test connector and a fourth test connector.

11. The computer system of claim 10, wherein the first test connector is configured for voltage testing.

12. The computer system of claim 10, wherein the third test connector is configured for ripple testing and noise testing.

13. The computer system of claim 12, wherein the second test connector is configured for connecting to filter capacitors during the ripple testing and noise testing.

14. The computer system of claim 13, wherein the filter capacitors are two multiple capacitors respectively with capacitance of 0.1 μF and 10 μF.

15. The computer system of claim 10, wherein the fourth test connector is configured for current testing by connecting to a precision resistor.

16. The computer system of claim 9, further comprising a circuit board, the test connector groups being positioned on the circuit board.
